(19) United States
(12) Patent Application Publication
(10) Pub. No.: US 2026/0189248 A1
(43) Pub. Date: Jul. 2, 2026

(54) CRC CHECK SYSTEM AND METHOD, STORAGE MEDIUM, AND PROGRAM PRODUCT

(71) Applicant: Black Sesame Technologies Co., Ltd., Wuhan (CN)

(72) Inventors: Zhihan Zhang, Shanghai (CN); Hua Wang, Shanghai (CN)

(73) Assignee: Black Sesame Technologies Co., Ltd., Wuhan (CN)

(21) Appl. No.: 19/431,727

(22) Filed: Dec. 23, 2025

(30) Foreign Application Priority Data
Jan. 2, 2025 (CN) 202510007868.2

(51) Int. Cl. H03M 13/09

(52) U.S. Cl. CPC H03M 13/09

(57) ABSTRACT

The present disclosure discloses a cyclic redundancy check (CRC) check system, including an upper-computer control apparatus and a programmable CRC circuit. The programmable CRC circuit checks to-be-checked data to generate a check result. The upper-computer control apparatus determines a plurality of parameters of the programmable CRC circuit according to a communication scenario, and applies the plurality of parameters to the programmable CRC circuit, to non-volatilely program a structure and a function of the programmable CRC circuit according to the communication scenario; calculates an expected CRC result; acquires the to-be-checked data, and sends the to-be-checked data to a non-volatilely programmed programmable CRC circuit; reads a check result generated by the non-volatilely programmed programmable CRC circuit, and compares the check result with the expected CRC result; and instructs, in response to the check result being inconsistent with the expected CRC result, the master to resend the data to the slave.

### RELATED APPLICATION

This application claims the benefit under 35 U.S.C. § 119(a) of the filing date of Chinese Patent Application No. 202510007868.2, filed in the Chinese Patent Office on Jan. 2, 2025. The disclosure of the foregoing application is herein incorporated by reference in its entirety.

### TECHNICAL FIELD

The present invention relates to the field of cyclic redundancy check (CRC) check, and in particular, to a CRC check system and method, a storage medium, and a program product.

### BACKGROUND

Advances in integrated circuit manufacturing processes have led to higher operating frequencies and smaller on-chip interconnect distances in systems on chip, increasing a probability of erroneous signal inversion and inter-stage signal crosstalk, and making on-chip data stream transmission check increasingly critical. CRC check is widely used in large-scale data stream communication due to a high error detection rate and a low implementation cost. An existing CRC check system has a fixed circuit structure, leading to difficulty in adaptation to flexible changes in different application scenarios and an incomplete security check mechanism, which easily causes data errors.

### SUMMARY

The present disclosure provides a CRC check system, a CRC check method, a non-transitory computer-readable storage medium, and a computer program product.

In one aspect, the present disclosure relates to a CRC check system, for checking data sent from a master to a slave, including an upper-computer control apparatus and a programmable CRC circuit; the programmable CRC circuit being configured to check to-be-checked data to generate a check result; the upper-computer control apparatus includes: a parameter configuration module configured to determine a plurality of parameters of the programmable CRC circuit according to a communication scenario between the master and the slave, and apply the plurality of parameters to the programmable CRC circuit, to non-volatilely program a structure and a function of the programmable CRC circuit according to the communication scenario; an expected calculation module configured to calculate an expected CRC result through software based on data to be sent to the slave by the master; a data scheduling module configured to acquire data to be received by the slave as the to-be-checked data, and send the to-be-checked data to a non-volatilely programmed programmable CRC circuit; a result reading module configured to read a check result generated by the non-volatilely programmed programmable CRC circuit upon completion of check on the to-be-checked data, and compare the check result with the expected CRC result; and an operation response module configured to instruct, in response to the check result generated by the non-volatilely programmed programmable CRC circuit being inconsistent with the expected CRC result, the master to resend the data to the slave.

In some embodiments, the programmable CRC circuit includes: a parameter non-volatile programming sub-circuit configured to receive the plurality of parameters, and non-volatilely program a CRC check algorithm and an actual operating circuit structure of the programmable CRC circuit based on the plurality of parameters; a check sub-circuit configured to check the to-be-checked data to generate the check result; an interrupt sub-circuit configured to generate an interrupt signal in response to an event occurring during the check on the to-be-checked data by the non-volatilely programmed programmable CRC circuit; and a result memory configured to store the check result generated by the check sub-circuit.

In some embodiments, the check sub-circuit includes a first check sub-circuit and a second check sub-circuit with identical structures, the first check sub-circuit and the second check sub-circuit each including a serial CRC structure circuit and a parallel CRC structure circuit and being each configured to check the to-be-checked data to generate a check result; and the serial CRC structure circuit having a pipeline-stage-configurable circuit structure, and the parallel CRC structure circuit having a systolic matrix array carry structure.

In some embodiments, the parameter configuration module of the upper-computer control apparatus is further configured to determine, according to the communication scenario between the master and the slave, one or more of the following parameters of the programmable CRC circuit: a lockstep enable parameter indicating whether to enable both the first check sub-circuit and the second check sub-circuit; a selection enable parameter indicating which of the serial CRC structure circuit and the parallel CRC structure circuit is selected; delay parameters of the first check sub-circuit and the second check sub-circuit when both the first check sub-circuit and the second check sub-circuit are enabled; a number of pipeline stages of the pipeline-stage-configurable circuit structure when the serial CRC structure circuit is selected; and a matrix configuration parameter of the systolic matrix array carry structure when the parallel CRC structure circuit is selected.

In some embodiments, the upper-computer control apparatus further includes a data collation module; the data collation module being configured to classify, according to master IDs and slave IDs, all the data to be sent to the slave by the master into one or more data sets, the data with identical master IDs and identical slave IDs belonging to a same data set; the expected calculation module is further configured to calculate, in units of the data sets, one or more expected CRC results respectively corresponding to the one or more data sets through software; and the result reading module is further configured to read one or more check results respectively corresponding to the one or more data sets generated by the non-volatilely programmed programmable CRC circuit upon completion of the check on the to-be-checked data in units of the data sets, and compare the one or more check results respectively with the one or more expected CRC results.

In some embodiments, the upper-computer control apparatus further includes a monitoring module configured to monitor an interrupt signal generated by the interrupt sub-circuit of the non-volatilely programmed programmable CRC circuit; and the operation response module of the upper-computer control apparatus is further configured to perform, in response to monitoring the interrupt signal, processing corresponding to the monitored interrupt signal.

In some embodiments, the interrupt sub-circuit of the non-volatilely programmed programmable CRC circuit is further configured to generate, in response to an operational error of the non-volatilely programmed programmable CRC circuit, an internal error interrupt as the interrupt signal; and generate, in response to the non-volatilely programmed programmable CRC circuit generating a predetermined number of check results, a check result interrupt as the interrupt signal; and the operation response module of the upper-computer control apparatus is further configured to issue, in response to monitoring the internal error interrupt, an instruction to fix an error; and instruct, in response to monitoring the check result interrupt, the result reading module to read the check result from the result memory of the non-volatilely programmed programmable CRC circuit for comparison.

In some embodiments, the interrupt sub-circuit of the non-volatilely programmed programmable CRC circuit is further configured to generate, in a case where both the first check sub-circuit and the second check sub-circuit are enabled, the internal error interrupt when a check result generated by the first check sub-circuit is inconsistent with a check result generated by the second check sub-circuit; and the operation response module of the upper-computer control apparatus is further configured to reset, in response to monitoring the internal error interrupt, the non-volatilely programmed programmable CRC circuit and re-perform the check on the to-be-checked data.

In some embodiments, the result memory of the non-volatilely programmed programmable CRC circuit includes, based on the plurality of parameters, a plurality of result interrupt state registers respectively corresponding to the plurality of data sets and a plurality of sub-storage spaces respectively corresponding to the plurality of data sets, each of the result interrupt state registers being configured to indicate completion of check on the corresponding data set, and each of the sub-storage spaces being configured to store a check result of the corresponding data set; and the result reading module of the upper-computer control apparatus is further configured to: check, in response to the monitoring module monitoring the check result interrupt, the one or more result interrupt state registers to determine the data set on which the check is completed, read the check result generated by the non-volatilely programmed programmable CRC circuit from the sub-storage space corresponding to the data set on which the check is completed, and compare the check result with the expected CRC result.

In another aspect of the present disclosure, a CRC check method is provided, for checking data sent from a master to a slave, including: determining a plurality of parameters of a programmable CRC circuit according to a communication scenario between the master and the slave, and applying the plurality of parameters to the programmable CRC circuit, to non-volatilely program a structure and a function of the programmable CRC circuit according to the communication scenario; calculating an expected CRC result through software based on data to be sent to the slave by the master; acquiring data to be received by the slave as the to-be-checked data, and sending the to-be-checked data to a non-volatilely programmed programmable CRC circuit; reading a check result generated by the non-volatilely programmed programmable CRC circuit upon completion of check on the to-be-checked data, and comparing the check result with the expected CRC result; and instructing, in response to the check result generated by the non-volatilely programmed programmable CRC circuit being inconsistent with the expected CRC result, the master to resend the data to the slave.

In another aspect of the present disclosure, a non-transitory computer-readable storage medium is provided, having a computer program stored therein, wherein when the computer program is executed by a processor, the CRC check method above is implemented.

In another aspect of the present disclosure, a computer program product is provided, including a computer program stored therein, wherein when the computer program is executed by a processor, the CRC check method above is implemented.

According to the CRC check system, the CRC check method, the computer-readable storage medium, and the computer program product, the upper-computer control apparatus controls and schedules operation of the programmable CRC circuit. A structure and a function of the programmable CRC circuit may be non-volatilely programmed according to a communication scenario between the master and the slave, so the structure and the function of the programmable CRC circuit may be flexibly changed according to an actual requirement. Therefore, the CRC check system according to the present disclosure can adapt to various different communication scenarios, greatly improving application flexibility. In addition, the expected CRC result is calculated through software, which reduces a hardware computational load on the programmable CRC circuit. At the same time, the expected CRC result calculated through the software is compared with a check result calculated through hardware of the programmable CRC circuit, which can improve reliability of check and improve a security mechanism of the CRC check system.

### BRIEF DESCRIPTION OF THE DRAWINGS

FIG. 1 is a schematic structural block diagram of a CRC check system according to embodiments of the present disclosure;

FIG. 2 is a schematic structural block diagram of the CRC check system according to embodiments of the present disclosure;

FIG. 3 is a schematic structural block diagram of a check sub-circuit according to embodiments of the present disclosure;

FIG. 4 is a schematic diagram of a pipeline-stage-configurable circuit structure according to embodiments of the present disclosure;

FIG. 5 is a schematic diagram of a systolic matrix array carry structure according to embodiments of the present disclosure;

FIG. 6 is a schematic structural diagram of a result memory according to embodiments of the present disclosure; and

FIG. 7 is a flowchart of a CRC check method according to embodiments of the present disclosure.

### DETAILED DESCRIPTION

In the field of data security check, with prominent advantages of a high error detection rate and a low implementation cost, CRC check is widely used in large-scale data stream communication scenarios. An existing CRC check system has a fix circuit structure, leading to difficulty in adaptation to flexible changes in different application scenarios and an incomplete security check mechanism, which easily causes data errors. Based on this, the present disclosure provides a CRC check system and method, a storage medium, and a program product that can adapt to various communication scenarios and have an improved data check mechanism. The CRC check system and method, the storage medium, and the program product according to the present disclosure may be used in a vehicle-mounted field for checking communication data during communication among various devices in a vehicle, thereby ensuring accuracy and security of data streams transmitted within a vehicle-mounted system.

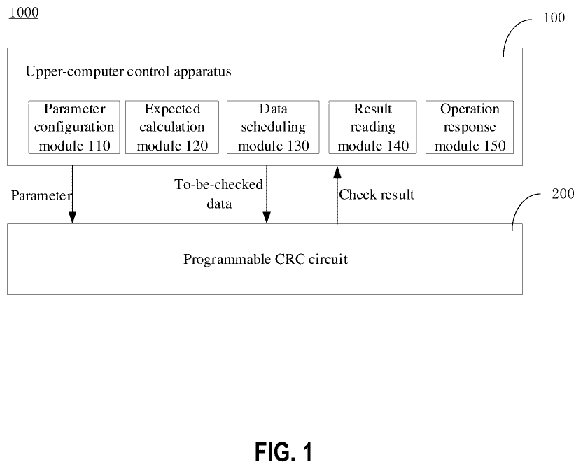

FIG. 1 is a schematic structural block diagram of a CRC check system 1000 according to embodiments of the present disclosure. The CRC check system 1000 is configured to check data sent from a master to a slave, including an upper-computer control apparatus 100 and a programmable CRC circuit 200. The data sent from the master to the slave is transmitted through a physical link. The CRC check system 1000 is configured to check whether a transmission error occurs in the data during data transmission over the physical link.

The upper-computer control apparatus 100 and the programmable CRC circuit 200 may be in communication connection. The upper-computer control apparatus 100 is implemented by a computing apparatus, such as a computer or an embedded device with similar functions. The upper-computer control apparatus 100 runs dedicated control software. The software is developed based on an operating system platform and utilizes various programming interfaces and library functions to interact with the programmable CRC circuit 200 and calculate and configure various parameters, which is responsible for controlling and scheduling the operation of the programmable CRC circuit 200, achieving comprehensive control over a CRC check process. It should be understood that the upper-computer control apparatus 100 can also interact with the master and the slave.

The programmable CRC circuit 200 is an execution core of the CRC check system, configured to check to-be-checked data to generate a check result. Specifically, the programmable CRC circuit 200 receives parameters from the upper-computer control apparatus and then performs CRC check calculation on inputted to-be-checked data. For example, the CRC circuit 200 according to the embodiments of the present disclosure is an application-specific integrated circuit (ASIC), including basic digital circuit elements such as a shift register and an XOR gate. These elements are connected and operate in coordination according to the parameters set by the upper-computer control apparatus 100, to implement the function of the CRC circuit.

The upper-computer control apparatus 100 includes a parameter configuration module 110, an expected calculation module 120, a data scheduling module 130, a result reading module 140, and an operation response module 150. It is easy to understand that various functions of the upper-computer control apparatus 100 are implemented by software. For example, the upper-computer control apparatus 100 implements the functions of the above modules with a processor executing software programs.

The parameter configuration module 120 is configured to determine a plurality of parameters of the programmable CRC circuit 200 according to a communication scenario between the master and the slave, and apply the plurality of parameters to the programmable CRC circuit 200, to non-volatilely (persistently) program a structure and a function of the programmable CRC circuit 200 according to the communication scenario.

The master and the slave are devices that exchange data with each other. The master is a device or node that initiates transmission of data or instructions, while the slave is responsible for receiving the data or instructions from the master. For example, in a vehicle-mounted system, a CPU or an ECU as a master may send data or instructions to a plurality of sensors that act as slaves.

In some embodiments, the upper-computer control apparatus 100 may have a same physical entity as one or more masters (i.e., operate based on the same physical entity). In this case, the functions of the upper-computer control apparatus 100 are implemented by the master running corresponding software, and the parameters determined by the parameter configuration module 120 of the upper-computer control apparatus 100 are applied to the programmable CRC circuit 200 through a physical interface of the master. Alternatively, the upper-computer control apparatus 100 may be a separate physical entity different from the master (i.e., operate based on different physical entities). In this case, the functions of the upper-computer control apparatus 100 are implemented by running corresponding software, and the parameters determined by the parameter configuration module 120 of the upper-computer control apparatus 100 are applied to the programmable CRC circuit 200 through an own physical interface. Under various circumstances, the upper-computer control apparatus 100 can communicate with and control the master. In short, distinguishing the concepts of the master and the upper-computer control apparatus 100 does not necessarily imply a difference in specific physical deployment thereof, but only a difference in software function levels thereof. Software with different functions may have a unified physical entity and share a set of interfaces, or may be applied to different physical entities and thus act on different interfaces. In the present disclosure, the master and the upper-computer control apparatus 100 respectively have functions of generating data to be sent to the slave and controlling the operation of the programmable CRC circuit. As an example, the respective functions may be implemented, for example, by running different functional software on mutually different physical entities. In this case, the master and the upper-computer control apparatus 100 respectively have mutually different physical entities and can communicate with each other.

The communication scenario between the master and the slave is, for example, numbers of the master and the slave participating in communication, a communication manner, a node traffic volume, and the like. The numbers of the master and the slave refer to a number of devices participating in communication. The communication manner is, for example, serial communication, parallel communication, or network-based communication. The node traffic volume refers to an amount of data transmitted or received by each device node per unit of time.

The plurality of parameters of the programmable CRC circuit 200 mainly include CRC algorithm parameters and system operating parameters. The CRC algorithm parameters refer to which CRC algorithm the programmable CRC circuit 200 uses when performing check. Common CRC algorithms include, for example, CRC-8, CRC-16, and CRC-32. Different algorithms have different generator polynomials, resulting in varying error detection capabilities and applicable scenarios. For example, the CRC-8 algorithm is relatively simple and has a fast computing speed, suitable for scenarios that do not require extremely high data accuracy, involve small data volumes, and demand higher real-time performance, for example, some simple short-message transmission or internal data check in small-scale devices. CRC-32, due to properties of generator polynomials, has a stronger error detection capability and can detect more types of errors, but involves a large amount of computation, suitable for scenarios that demand extremely high data integrity and involve large volumes of data transfer, such as in network file transfer or data storage check for large-scale databases. Selection of a CRC check algorithm should be based on a comprehensive trade-off among factors such as data importance, data volume, and real-time requirements in a real-time application scenario, ensuring that check accuracy is achieved without affecting overall system operational efficiency. The CRC algorithm parameters include a CRC polynomial coefficient, a CRC register initial value, and a CRC polynomial bit width, and the like, which are used to implement the corresponding CRC algorithm through a hardware circuit.

The system operating parameters are internal configuration required for the operation of the programmable CRC circuit 200, and are used to construct an actual operating circuit structure of the programmable CRC circuit 200, including, for example, a number of various registers, interrupt control parameters (such as an interrupt trigger condition and an interrupt priority assignment), and parameters for configuring the circuit structure. After the plurality of parameters of the programmable CRC circuit 200 are determined, the plurality of parameters are applied to the programmable CRC circuit 200, thereby enabling the programmable CRC circuit 200 to implement, according to the plurality of parameters, the functions desired by the upper-computer control apparatus 100. In a specific embodiment, the parameters are, for example, loaded, by using a hardware description language, into an ASIC serving as the programmable CRC circuit 200, and the ASIC configures a corresponding circuit structure according to the parameters and loads an algorithm, to implement functions corresponding to the parameters. More specific system operating parameters will be described in detail hereinafter.

Non-volatilely programing the structure and the function of the programmable CRC circuit 200 means determining, by using a hardware description language, an internal structure and implementable functions of a CRC circuit that originally has a certain degree of programmability.

The expected calculation module 120 is configured to calculate an expected CRC result through software based on data to be sent to the slave by the master. The expected calculation module 120 acquires, in advance, the data to be sent to the slave by the master, and calculates the expected CRC result of the to-be-sent data on a software side by using a software algorithm. The data to be sent to the slave by the master is master-side data, and refers to data prior to transmission over a physical link (e.g., hardware circuit), i.e., data that is on the master side and has not been transmitted over the physical link. The expected CRC result herein is a CRC check code that should be obtained under ideal, error-free conditions by using the same CRC algorithm as the non-volatilely programmed programmable CRC circuit 200. The expected CRC result may be stored in a predetermined storage module of the upper-computer control apparatus 100.

The data scheduling module 130 is configured to acquire data to be received by the slave as the to-be-checked data, and send the to-be-checked data to a non-volatilely programmed programmable CRC circuit.

Data transmission from the master to the slave proceeds normally via the physical link. During the transmission, when data is transmitted to a side close to the slave, a copy of the transmitted data is bypassed to the CRC check system 1000. Therefore, the data scheduling module 130 of the upper-computer control apparatus 100 acquires data to be received by the slave (i.e., the data bypassed during the transmission) as the to-be-checked data. The CRC check system 1000 may be arranged close to one side of the slave, thereby checking the data to be received by the slave. The data to be received by the slave is slave-side data, which refers to data to be sent to the slave after passing through a physical link from the master to the slave.

Preferably, the data scheduling module 130 of the upper-computer control apparatus 100 is required to consider a maximum data computation amount of the non-volatilely programmed programmable CRC circuit 200 during the sending of the to-be-checked data. For example, when the non-volatilely programmed programmable CRC circuit 200 supports computation of only 100 pieces of data, if there are more than 100 pieces of data to be sent by the master to the slave, such data is bypassed to the CRC check system 1000 as the to-be-checked data during the transmission to the slave, the to-be-checked data bypassed to the CRC check system 1000 is temporarily stored in a predetermined storage part of the upper-computer control apparatus 100, and the data scheduling module 140 of the upper-computer control apparatus 100 schedules the data from the predetermined storage part in batches not exceeding 100 pieces during each transmission and sends the data transmitted from the master to the slave to the non-volatilely programmed programmable CRC circuit 200.

The result reading module 140 is configured to read a check result generated by the non-volatilely programmed programmable CRC circuit upon completion of check on the to-be-checked data, and compare the check result with the expected CRC result.

The non-volatilely programmed programmable CRC circuit 200 generates the check result through calculation by a hardware structure thereof, for example, a check code generated by the non-volatilely programmed programmable CRC circuit 200. The expected CRC result calculated through software is calculated based on the data to be sent by the master, while the check result calculated through the non-volatilely programmed programmable CRC circuit 200 is calculated based on the data to be received by the slave (i.e., data transmitted to the side close to the slave through the physical link). Whether an error occurs in the data during the transmission can be determined by comparing the check result with the expected CRC result calculated through a software algorithm. If the check result generated by calculation through the hardware of the non-volatilely programmed programmable CRC circuit 200 is consistent with the expected CRC result, it is considered that the data transmitted from the master to the slave is error-free.

The operation response module 150 is configured to instruct, in response to the check result generated by the non-volatilely programmed programmable CRC circuit being inconsistent with the expected CRC result, the master to resend the data to the slave.

If the result reading module 140 obtains through comparison that the check result generated by the non-volatilely programmed programmable CRC circuit is inconsistent with the expected CRC result, it is considered that an error occurs in the data from the master to the slave during the transmission, and thus the master is instructed to resend the to-be-sent data to the slave. During the resending of the to-be-sent data to the slave by the master, the data scheduling module 130 of the upper-computer control apparatus 100 resends the data received by the slave as the to-be-checked data to the non-volatilely programmed programmable CRC circuit 200 for check, until the check result generated by the non-volatilely programmed programmable CRC circuit 200 is consistent with the expected CRC result.

According to the CRC check system 1000 in the above embodiments, the upper-computer control apparatus 100 controls and schedules the operation of the programmable CRC circuit 200. A structure and a function of the programmable CRC circuit 200 may be non-volatilely programmed according to a communication scenario between the master and the slave, so the structure and the function of the programmable CRC circuit 200 may be flexibly changed according to an actual requirement. Therefore, the CRC check system 1000 according to the above embodiments can adapt to various different communication scenarios, greatly improving application flexibility. In addition, the expected CRC result is calculated through software, which reduces a hardware computational load on the programmable CRC circuit 200. At the same time, the expected CRC result calculated through the software is compared with a check result calculated through hardware of the programmable CRC circuit 200, which can improve reliability of check and improve a security mechanism of the CRC check system 1000.

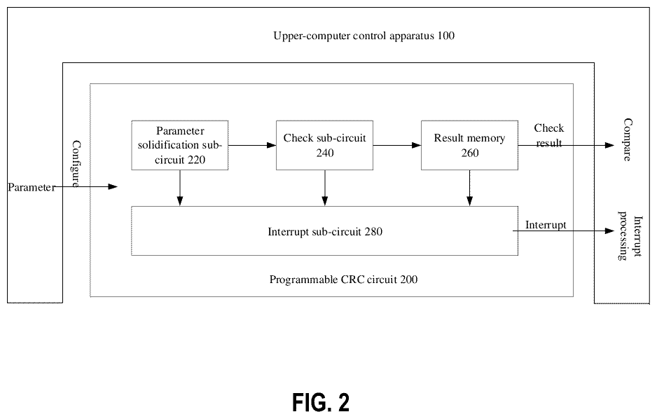

In some embodiments, referring to FIG. 2, the programmable CRC circuit 200 includes a parameter non-volatile programming sub-circuit 220, a check sub-circuit 240, a result memory 260, and an interrupt sub-circuit 280.

The parameter non-volatile programming sub-circuit 220 is configured to receive the plurality of parameters, and non-volatilely program a CRC check algorithm and an actual operating circuit structure of the programmable CRC circuit 200 based on the plurality of parameters. As described above, the upper-computer control apparatus 100 determines the plurality of parameters of the programmable CRC circuit 200 according to the communication scenario. The parameter non-volatile programming sub-circuit 220 is configured to, for example, apply the parameters to a main circuit (e.g., the check sub-circuit 240, the result memory 260, and the interrupt sub-circuit 280), so as to non-volatilely program the programmable CRC circuit 200 according to the parameters. More specifically, the check sub-circuit 240, the result memory 260, and the interrupt sub-circuit 280 are non-volatilely programmed, to enable the non-volatilely programmed programmable CRC circuit 200 to operate according to preset parameters. The programmable CRC circuit 200 non-volatilely programmed by the parameter non-volatile programming sub-circuit 220 is the non-volatilely programmed programmable CRC circuit 200.

The check sub-circuit 240 is configured to check the to-be-checked data to generate the check result. The check sub-circuit 240 is configured to perform CRC check calculation on the data to generate the check result.

The interrupt sub-circuit 280 is configured to generate an interrupt signal in response to a predetermined event occurring during the check on the to-be-checked data by the non-volatilely programmed programmable CRC circuit 200. The interrupt sub-circuit 280 is mainly responsible for monitoring various key events and states of the programmable CRC circuit 200 during the operation, and generating an interrupt signal in a timely manner and reporting the interrupt signal to the upper-computer control apparatus 100 when a predetermined event occurs, such as occurrence of an internal error, completion of data transmission, or arrival of a specific time threshold.

The result memory 260 is configured to store the check result generated by the check sub-circuit 240. The check result (e.g., a check code) generated by the check sub-circuit 240 is stored in the result memory 260.

It is easy to understand that the programmable CRC circuit 200 being non-volatilely programmed means that the check sub-circuit 240, the interrupt sub-circuit 280, and the result memory 260 in the programmable CRC circuit 200 are non-volatilely programmed, to obtain the check sub-circuit 240, the result memory 260, and the interrupt sub-circuit 280 of the non-volatilely programmed programmable CRC circuit 200.

According to the CRC check system 1000 in the above embodiments, the structure and the function of the programmable CRC circuit 200 may be non-volatilely programmed according to the communication scenario between the master and the slave. More specifically, the check sub-circuit 240, the result memory 260, and the interrupt sub-circuit 280 may be configured according to the parameters received by the parameter non-volatile programming sub-circuit 220. Therefore, the structure and the function of the programmable CRC circuit 200 can be flexibly changed according to an actual requirement.

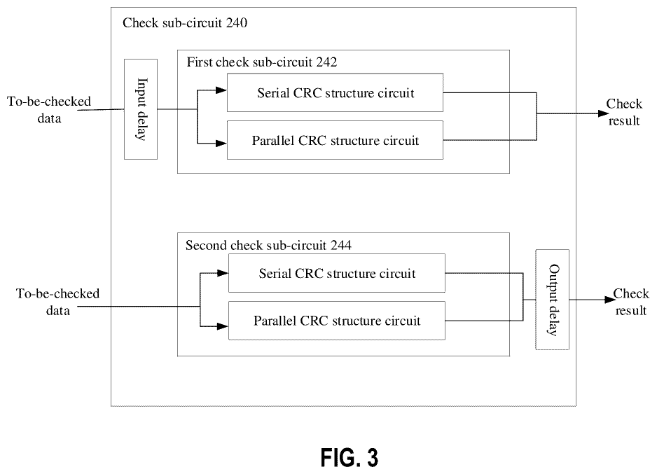

In some embodiments, referring to FIG. 3, the check sub-circuit includes a first check sub-circuit 242 and a second check sub-circuit 244 with identical structures, the first check sub-circuit 242 and the second check sub-circuit 244 each include a serial CRC structure circuit and a parallel CRC structure circuit and are each configured to check the to-be-checked data to generate a check result. The serial CRC structure circuit calculates the check result in a serial result carry manner, while the parallel CRC structure circuit can process multi-bit data simultaneously, thereby calculating the check result in parallel.

In this embodiment, the serial CRC structure circuit has a pipeline-stage-configurable circuit structure, and the parallel CRC structure circuit has a systolic matrix array carry structure.

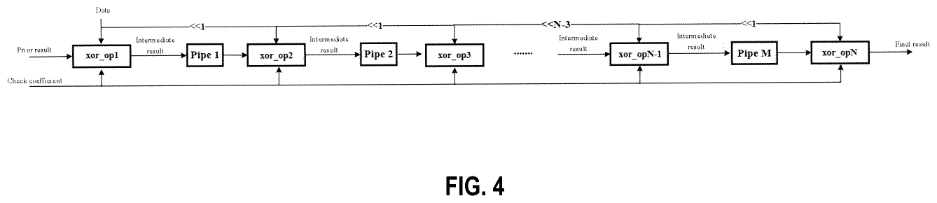

FIG. 4 is a schematic diagram of a pipeline-stage-configurable circuit structure according to embodiments of the present disclosure. In the pipeline-stage-configurable circuit structure, a data processing flow is divided into a plurality of pipeline stages based on the serial CRC structure circuit, and a number of the pipeline stages may be adjusted according to a requirement of an actual communication scenario. In specific implementation, the data processing flow is divided into a plurality of pipeline stages by inserting pipeline registers into a computing path. N pipeline registers are inserted to divide the computing path into N+1 segments, and each segment has a shorter length, thereby adapting to higher hardware operating frequencies. A number of the inserted pipeline registers may be configured by the upper-computer control apparatus 100 through software. Therefore, different numbers of pipeline registers may be configured in different communication scenarios, corresponding to different system operating frequencies. In the example shown in FIG. 4, xor_op1, xor_op2, xor_op3, xor_opN-1, and xor_opN represent bit-by-bit CRC check operations, while Pipe 1, Pipe 2, . . . , and Pipe M represent the inserted pipeline registers. Check coefficients (Poly_i) are CRC coefficients at respective register stages on a CRC serial pipeline computing path. These coefficients determine how each stage of registers participates in the CRC check calculation during bit-by-bit processing of data along a serial path. The check coefficients reflect how each stage should perform an XOR operation on the data to progressively generate a CRC check code.

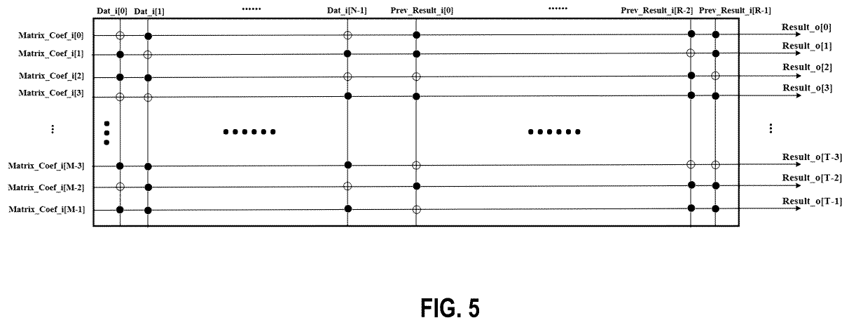

FIG. 5 is a schematic diagram of a systolic matrix array carry structure according to embodiments of the present disclosure. In the systolic matrix array carry structure, based on parallel CRC computing, computing units are organized in a matrix array, and carry signals are transferred between units in a matrix in a special systolic carry manner, to implement high-speed and accurate CRC check on large-scale data. Matrix configuration parameters of the systolic matrix array carry structure may be configured by the upper-computer control apparatus 100 through software. In the example shown in FIG. 5, Matrix_Coef[i] represents a value of an i^{th} systolic matrix parameter, Dat_i[i] represents a value of an i^{th} piece of current to-be-checked data, and prev_result represents a previous calculation result of a check data stream in a current batch. FIG. 5 shows a two-dimensional systolic matrix array carry structure, whose parameters also exist in the form of two-dimensional matrices in each internal processing unit. In FIG. 5, a solid dot indicates presence of an actual calculation parameter at the position, while a hollow dot indicates that no calculation parameter is configured at the position, which is 0 by default.

According to the CRC check system 1000 in the above embodiments, the check sub-circuit 240 includes a first check sub-circuit 242 and a second check sub-circuit 244 with identical structures, indicating that the check sub-circuit 240 has undergone lockstep processing. Lockstep is a security mechanism that involves two or more completely identical processing units. These processing units are completely identical in hardware design, including circuit structures and element parameters. The units receive identical instructions or data as input, and after the processing units complete operations, a dedicated comparison circuit compares output results thereof. Lockstep provides reliability and security of the check sub-circuit 240. Further, the serial CRC structure circuit has a pipeline-stage-configurable circuit structure. A specific serial CRC structure circuit may be configured according to an actual situation, thereby increasing an actual application space. The parallel CRC structure circuit has a systolic matrix array carry structure, which significantly improves operational efficiency of the circuit on the premise of maintaining almost a same implementation area.

In some embodiments, the parameter configuration module 110 of the upper-computer control apparatus 100 is further configured to determine, according to the communication scenario between the master and the slave, one or more of the following parameters of the programmable CRC circuit 200: a lockstep enable parameter indicating whether to enable both the first check sub-circuit 242 and the second check sub-circuit 244, a selection enable parameter indicating which of the serial CRC structure circuit and the parallel CRC structure circuit is selected, delay parameters of the first check sub-circuit 242 and the second check sub-circuit 244 when both the first check sub-circuit 242 and the second check sub-circuit 244 are enabled, a number of pipeline stages of the pipeline-stage-configurable circuit structure when the serial CRC structure circuit is selected, and a matrix configuration parameter of the systolic matrix array carry structure when the parallel CRC structure circuit is selected.

The lockstep enable parameter indicating whether to enable both the first check sub-circuit 242 and the second check sub-circuit 244 is a parameter indicating whether to enable lockstep. When both the first check sub-circuit 242 and the second check sub-circuit 244 are enabled, that is, when lockstep is enabled, the parameters of the programmable CRC circuit 200 determined by the parameter configuration module 110 of the upper-computer control apparatus 100 further include: delay parameters of the first check sub-circuit 242 and the second check sub-circuit 244. In the lockstep function, one of the first check sub-circuit 242 and the second check sub-circuit 244 performs delay processing at an input terminal, and the other performs delay processing at an output terminal, with delay times thereof being the same. The delay parameters refer to parameters used for delay processing at the input terminal or the output terminal.

The selection enable parameter indicating which of the serial CRC structure circuit and the parallel CRC structure circuit is selected refers to a parameter indicating whether the non-volatilely programmed programmable CRC circuit 200 employs the serial CRC structure circuit or the parallel CRC structure circuit. To reduce power consumption and processing overhead, only one structure circuit is enabled at a same moment. The serial CRC structure circuit and the parallel CRC structure circuit are respectively adapted to different processing scenarios: the serial CRC structure circuit is suitable for general scenarios with small data volumes, low speed requirements, and high area requirements, while the parallel CRC structure circuit is suitable for scenarios with large data volumes, high speed requirements, and low area requirements. The parameter configuration module 110 of the upper-computer control apparatus 100 may enable different circuit structures according to an actual communication scenario. When the lockstep function is enabled, both the first check sub-circuit 242 and the second check sub-circuit 244 are enabled. When the serial CRC structure circuit is selected, the serial CRC structure circuit is enabled in both the first check sub-circuit 242 and the second check sub-circuit 244. When the parallel CRC structure circuit is selected, the parallel CRC structure circuit is enabled in both the first check sub-circuit 242 and the second check sub-circuit 244. The parameters of the programmable CRC circuit 200 determined by the parameter configuration module 110 of the upper-computer control apparatus 100 further include a number of pipeline stages of the pipeline-stage-configurable circuit structure when the serial CRC structure circuit is selected. The parameters of the programmable CRC circuit 200 determined by the parameter configuration module 110 of the upper-computer control apparatus 100 further include a matrix configuration parameter of the systolic matrix array carry structure when the parallel CRC structure circuit is selected.

In other words, the upper-computer control apparatus 100 determines, according to the communication scenario between the master and the slave, that the plurality of parameters of the programmable CRC circuit 200 may include the above parameters.

Furthermore, the upper-computer control apparatus 100 determines, according to the communication scenario between the master and the slave, that the plurality of parameters of the programmable CRC circuit 200 may further include interrupt control parameters and a number of various registers. For example, the interrupt control parameters include interrupt trigger condition settings, interrupt priority arrangement, and the like. The various registers include, for example, an error interrupt state register, a result interrupt state register, and the like. The error interrupt state register and the result interrupt state register will be described in detail below.

Furthermore, the first check sub-circuit 242 and the second check sub-circuit 244 each include a plurality of CRC computing cores, which are pre-configured to execute different CRC algorithms. For example, the first check sub-circuit 242 and the second check sub-circuit 244 each include a CRC-8 core, a CRC-16 core, and a CRC-32 core, which are configured to execute CRC-8, CRC-16, and CRC-32 algorithms respectively. The upper-computer control apparatus 100 determines, according to the communication scenario between the master and the slave, to enable which CRC computing core in the first check sub-circuit 242 and the second check sub-circuit 244 of the programmable CRC circuit 200, thereby determining a CRC check algorithm of the programmable CRC circuit 200. Preferably, in the non-volatilely programmed programmable CRC circuit 200, only one CRC computing core is enabled, and a same CRC computing core is enabled in both the first check sub-circuit 242 and the second check sub-circuit 244, while the CRC computing cores not enabled are disabled, thereby reducing power consumption.

According to the CRC check system 1000 in the above embodiments, the upper-computer control apparatus 100 can determine, according to an actual communication scenario, whether to enable lockstep and select the serial CRC structure circuit or the parallel CRC structure circuit, and specific configuration parameters of the serial CRC structure circuit or the parallel CRC structure circuit can be configured according to an actual communication scenario.

In some embodiments, the upper-computer control apparatus 100 further includes a data collation module. The data collation module is configured to classify, according to master IDs and slave IDs, all the data to be sent to the slave by the master into one or more data sets. The data with identical master IDs and identical slave IDs belongs to a same data set. The expected calculation module 120 is further configured to calculate, in units of the data sets, one or more expected CRC results respectively corresponding to the one or more data sets through software, and the result reading module 140 is further configured to read one or more check results respectively corresponding to the one or more data sets generated by the non-volatilely programmed programmable CRC circuit upon completion of the check on the to-be-checked data in units of the data sets, and compare the one or more check results respectively with the one or more expected CRC results.

The CRC check system according to this embodiment may be applied to a communication process between one or more masters and one or more slaves. Each master has a master ID, and each slave has a slave ID, which serve as respective identifiers thereof. The data collation module acquires in advance the data to be sent to the slave by the master, and classifies sending nodes (master IDs) and destination nodes (slave IDs) of the data to be sent to the slave into a plurality of data sets. The data with identical master IDs and identical slave IDs (i.e., the data having identical transmission paths) belongs to a same data set. In some examples, the number of the data sets may be the number of masters×the number of slaves. That is, a transmission path from each master to each slave corresponds to one data set. In some other examples, the number of the data sets may be less than the number of masters×a number of slaves, and different combinations from masters to slaves may correspond to a same data set. Further, a data set ID is added to each data set, to serve as an identifier of the data set. Furthermore, a Start flag bit indicating start of transmission and an End flag bit indicating end of transmission are added to each data set, and corresponding flow control bits are added. The data in each data set is collated into a format supported by the programmable CRC circuit 200. The flow control bits are bits that identify sending nodes and destination nodes of the data, which may be data set IDs. The data collation module is a module interacting with the master. After being collated above, the data to be sent to the slave by the master is then transmitted by the master to the slave.

The expected calculation module 120 of the upper-computer control apparatus 100 calculates, in units of data sets, one or more expected CRC results through software, that is, calculates, for each data set, one expected CRC result corresponding to the data set.

Correspondingly, the check sub-circuit 240 of the non-volatilely programmed programmable CRC circuit 200 checks the to-be-checked data in units of the data sets, and generates one or more check results in one-to-one correspondence to the one or more data sets, and the result reading module 140 of the upper-computer control apparatus 100 compares the one or more check results respectively with the one or more expected CRC results. In this case, the result reading module of the upper-computer control apparatus 100 queries the data set ID for which the check result generated by the non-volatilely programmed programmable CRC circuit 200 is inconsistent with the expected CRC result, and instructs the corresponding master to resend the data corresponding to data set ID to the corresponding slave. In this way, it is easy for the upper-computer control apparatus 100 to determine the data set(s) in which an error occurs during the transmission. That is, it is easy to determine from which send node to which destination node an error occurs in the data transmission, thereby facilitating subsequent processing.

The CRC check system 1000 in the above embodiments may be applied to a communication process between one or more masters and one or more slaves, that is, a communication process from a plurality of sending nodes to a plurality of destination nodes. In this case, the to-be-checked data includes a plurality of data sets. The data scheduling module 130 of the upper-computer control apparatus 100 may send the plurality of data sets as the to-be-checked data to the non-volatilely programmed programmable CRC circuit 200 in at least one of the following manners: sequential sending of data in a same data set, out-of-order sending of data in a same data set, and alternate sending of data in different data sets.

The CRC check system 1000 according to the above embodiments may be applied to multi-master to multi-slave communication according to a requirement of an actual communication scenario, which is suitable for flexible expansion in scenarios where numbers and device types of master/slave devices change.

In some embodiments, the upper-computer control apparatus 100 further includes a monitoring module. The monitoring module is configured to monitor an interrupt signal generated by the interrupt sub-circuit 280 of the non-volatilely programmed programmable CRC circuit 200. The operation response module 150 of the upper-computer control apparatus 100 is further configured to perform, in response to monitoring the interrupt signal, processing corresponding to the monitored interrupt signal.

The interrupt sub-circuit 280 of the non-volatilely programmed programmable CRC circuit 200 generates, according to interrupt control parameters pre-configured by the parameter configuration module of the upper-computer control apparatus 100, interrupt signals according to a rule of the parameters. The interrupt signals will be reported to the upper-computer control apparatus 100, and the monitoring module of the upper-computer control apparatus 100 monitors triggering of the interrupt signals. According to the interrupt control parameters, the interrupt sub-circuit 280 of the non-volatilely programmed programmable CRC circuit 200 generates different types of interrupt signals during the operation. The operation response module 150 of the upper-computer control apparatus 100 performs corresponding processing according to types of the received interrupt signals. Various interrupt signals will be described in detail hereinafter.

According to the CRC check system 1000 in the above embodiments, the upper-computer control apparatus 100 monitors the operation of the non-volatilely programmed programmable CRC circuit 200, that is, monitors an overall check process of the non-volatilely programmed programmable CRC circuit 200, enabling prompt detection and handling of issues arising during the data check, thereby enhancing reliability of the CRC check system 1000.

In some embodiments, the interrupt sub-circuit 280 of the programmable CRC circuit 200 is further configured to generate, in response to an operational error of the non-volatilely programmed programmable CRC circuit 200, an internal error interrupt as the interrupt signal, and generate, in response to the non-volatilely programmed programmable CRC circuit 200 generating a predetermined number of check results, a check result interrupt as the interrupt signal. The operation response module 150 of the upper-computer control apparatus 100 is further configured to issue, in response to monitoring the internal error interrupt, an instruction to fix an error, and read, in response to monitoring the check result interrupt, the check result from the result memory 260 of the non-volatilely programmed programmable CRC circuit 200.

The non-volatilely programmed programmable CRC circuit 200 includes a plurality of error interrupt state registers. A number and configuration of the error interrupt state registers are also configured by the parameter configuration module 110 of the upper-computer control apparatus 100. When an operational error occurs in the non-volatilely programmed programmable CRC circuit 200, the corresponding error interrupt state register is set, and the interrupt sub-circuit 280 generates an internal error interrupt based on the set state of the error interrupt state register. The internal error interrupt is reported to the upper-computer control apparatus 100.

The operational error of the non-volatilely programmed programmable CRC circuit 200 includes, for example, a lockstep error, a register parity error, an upper-computer early readback error, and the like. The lockstep error occurs when two (or more) processing units that should generate a same output from a same input produce different outputs. For this situation, the operation response module 150 of the upper-computer control apparatus 100 may issue an instruction to reset the programmable CRC circuit 200. The register parity error occurs when data actually configured in a register is inconsistent with an expected value. For this situation, the operation response module 150 of the upper-computer control apparatus 100 may issue an instruction to reconfigure a register file. The upper-computer early readback error occurs when the upper-computer control apparatus 100 reads the check result prematurely before the non-volatilely programmed programmable CRC circuit 200 has completed check calculation. For this situation, the operation response module 150 of the upper-computer control apparatus 100 may issue an instruction to clear erroneous instructions caused by early readback. Furthermore, the operation response module 150 of the upper-computer control apparatus 100 may record the operational error of the programmable CRC circuit 200 into an error log based on the detected internal error interrupt. The instruction to fix an error may be sent to the non-volatilely programmed programmable CRC circuit 200, or may be sent to a specific module in the upper-computer control apparatus 100.

The result memory 260 of the non-volatilely programmed programmable CRC circuit 200 includes one or more result interrupt state registers. A number and configuration of the result interrupt state registers are also configured by the parameter configuration module 110 of the upper-computer control apparatus 100 according to the communication scenario. When the non-volatilely programmed programmable CRC circuit 200 completes check and generates a check result, the corresponding result interrupt state register is set, and the interrupt sub-circuit 280 generates a check completion interrupt in response to the result interrupt state register being set. The check completion interrupt is reported to the upper-computer control apparatus 100. The configuration of the result interrupt state register will be described in detail hereinafter.

The operation response module 150 of the upper-computer control apparatus 100 instructs, in response to monitoring the check result interrupt, the result reading module 140 to read the check result from the result memory 260 of the non-volatilely programmed programmable CRC circuit 200 for comparison.

According to the CRC check system 1000 in the above embodiments, the upper-computer control apparatus 100 monitors the operation of the non-volatilely programmed programmable CRC circuit 200, and performs different processing on different interrupt signals, which enhances an error correction capability and practicability of the CRC check system.

In some embodiments, the interrupt sub-circuit 280 of the non-volatilely programmed programmable CRC circuit 200 is further configured to generate, in a case where both the first check sub-circuit 242 and the second check sub-circuit 244 are enabled, the internal error interrupt when the check result generated by the first check sub-circuit 242 is inconsistent with the check result generated by the second check sub-circuit 244. The operation response module 150 of the upper-computer control apparatus 100 is further configured to reset, in response to monitoring the internal error interrupt, the non-volatilely programmed programmable CRC circuit and re-perform the check on the to-be-checked data.

“Both the first check sub-circuit 242 and the second check sub-circuit 244 are enabled” means that a lockstep function is enabled. “The check result generated by the first check sub-circuit 242 is inconsistent with the check result generated by the second check sub-circuit 244” means that the lockstep error occurs. In this case, the upper-computer control apparatus 100 resets the non-volatilely programmed programmable CRC circuit and re-performs the check on the to-be-checked data, to ensure accuracy of the check result.

According to the CRC check system 1000 in the above embodiments, the CRC check system 1000 incorporates lockstep detection, thereby improving check performance of the CRC check system 1000.

In some embodiments, the result memory 260 of the non-volatilely programmed programmable CRC circuit 200 includes, based on the plurality of parameters, a plurality of result interrupt state registers respectively corresponding to the plurality of data sets and a plurality of sub-storage spaces respectively corresponding to the plurality of data sets, each of the result interrupt state registers is configured to indicate completion of check on the corresponding data set, and each of the sub-storage spaces is configured to store a check result of the corresponding data set. The result reading module 140 of the upper-computer control apparatus 100 is further configured to: check, in response to the monitoring module monitoring the check result interrupt, the one or more result interrupt state registers to determine the data set on which the check is completed, read the check result generated by the non-volatilely programmed programmable CRC circuit 200 from the sub-storage space corresponding to the data set on which the check is completed, and compare the check result with the expected CRC result.

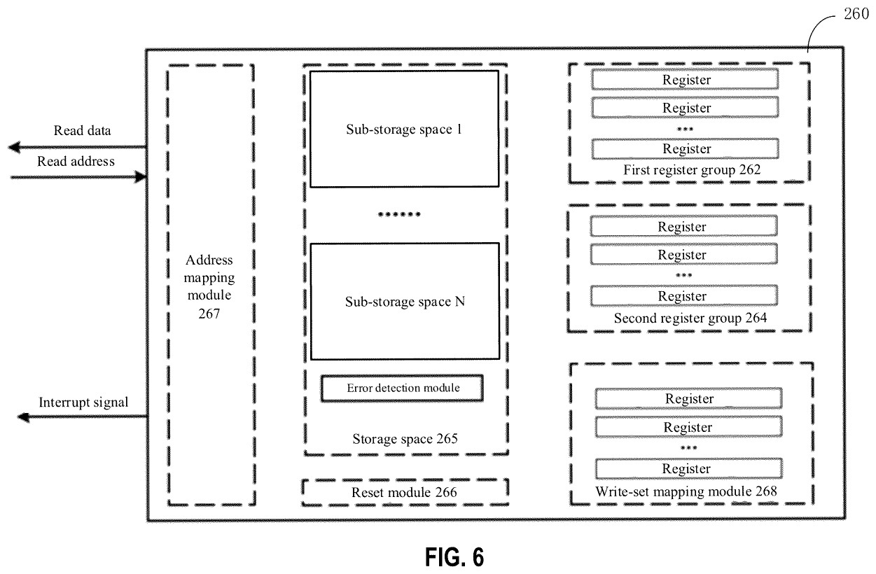

FIG. 6 shows a schematic structural diagram of the result memory 260 of the programmable CRC circuit 200. As shown in FIG. 6, the result memory 260 includes a first register group 262 and a second register group 264, each including a plurality of registers. The registers in the first register group 262 are used when an individual interrupt trigger occurs (which will be described in detail hereinafter). The first register group 262 includes a plurality of result interrupt state registers. Each result interrupt state register corresponds to a respective data set. A number of the plurality of result interrupt state registers included in the first register group 262 is configured by the parameter configuration module 110 of the upper-computer control apparatus 100, and is configured to be the same as the number of the data sets. That is, the data sets are in one-to-one correspondence to the result interrupt state registers. The second register group 264 is used when a batch interrupt trigger occurs (which will be described in detail hereinafter). Similar to the first register group 262, the second register group 264 includes a plurality of result interrupt state registers, and a number of the result interrupt state registers is configured by the parameter configuration module 110 of the upper-computer control apparatus 100, and is configured to be the same as the number of the data sets. That is, the data sets are in one-to-one correspondence to the result interrupt state registers. Each result interrupt state register is configured to indicate completion of check on the corresponding data set. More specifically, the non-volatilely programmed programmable CRC circuit 200 completes the check on the to-be-checked data in units of data sets, to generate one or more check results corresponding to the one or more data sets. There is a correspondence between the one or more result interrupt state registers and the one or more data sets. When the non-volatilely programmed programmable CRC circuit 200 completes the check on a certain data set and generates a corresponding check result, the result interrupt state register corresponding to the data set is set. For example, if a default value of the result interrupt state register is 0, upon completion of the check on the data set, the result interrupt state register corresponding to the data set is set to 1. Numbers of the result interrupt state registers and the sub-storage spaces and the correspondence to the data sets are configured according to the plurality of parameters determined by the parameter configuration module 110 of the upper-computer control apparatus 100.

More specifically, each time the non-volatilely programmed programmable CRC circuit generates a predetermined number of check results, for example, each time a predetermined number of result interrupt state registers are set, a check result interrupt is generated. For example, when the predetermined number is 1, each time the non-volatilely programmed programmable CRC circuit 200 completes a check (1 result interrupt state register is set), the interrupt sub-circuit 280 generates a check result interrupt, which is referred to as an individual interrupt trigger. For example, when the predetermined number is 10, each time the non-volatilely programmed programmable CRC circuit 200 completes 10 checks (10 result interrupt state registers are set), the interrupt sub-circuit 280 generates a check result interrupt. The situation in which the predetermined number is greater than 1 is referred to as a batch interrupt trigger. The predetermined number may be set by the parameter configuration module 110 of the upper-computer control apparatus 100 according to an actual communication scenario, serving as parameters of the programmable CRC circuit 200. For example, in application scenarios of large-scale, multi-data-set transmission, the predetermined number is set to a value greater than 1, and the check result interrupt is triggered only when a batch of check results are generated, which can reduce a number of times of triggering of the check result interrupt, thereby alleviating a response load on the upper-computer control apparatus 100.

In addition, the first register group 262 and the second register group 264 may also include upper-computer early readback error flag registers. A number thereof may be configured to be the same as the number of the result interrupt state registers, to identify upper-computer early readback events occurring in the corresponding data sets. In one configuration, only one of the first register group 262 and the second register group 264 is enabled.

As shown in FIG. 5, the result memory 260 further includes a storage space 266. The storage space 266 is divided into a plurality of sub-storage spaces. A number of the sub-storage spaces is configured by the parameter configuration module 110 of the upper-computer control apparatus 100, and is configured to be the same as the number of the data sets. That is, the data sets are in one-to-one correspondence to the sub-storage spaces. When the check sub-circuit 240 of the non-volatilely programmed programmable CRC circuit 200 completes the check on one data set and generates a check result, the check result is stored in the sub-storage space corresponding to the data set.

When the monitoring module of the upper-computer control apparatus 100 detects a check result interrupt, it means that the check on the data set is completed in the non-volatilely programmed programmable CRC circuit 200. The result reading module 140 of the upper-computer control apparatus 100 checks the one or more result interrupt state registers to determine the data set(s) on which the check is completed, more specifically, determine a data set ID for which the check is completed, reads the check result generated by the non-volatilely programmed programmable CRC circuit 200 from the sub-storage space corresponding to the data set on which the check is completed, and compares the check result with the expected CRC result.

In practical applications, since the number of the data sets is the same as the numbers of the result interrupt state registers and the sub-storage spaces, division of fewer data sets can reduce numbers of the result interrupt state registers, the sub-storage spaces, and other registers, thereby lowering the hardware overhead. Therefore, the data collation module of the upper-computer control apparatus 100 can minimize the number of the data sets according to the communication scenario. For example, if M masters transmit data to N slaves, but first M/2 masters send the data to the N slaves during first transmission and last M/2 masters send the data to the N slaves during second transmission, the number of the data sets may be set to (M/2×N), rather than (M×N).

Furthermore, the storage space 265 of the result memory 260 further includes an error detection module configured to self-check possible storage errors inside the storage space 265 of the result memory 260. When a storage error occurs, the interrupt sub-circuit 280 is notified to generate an internal error interrupt as an interrupt signal.

Furthermore, the result memory 260 further includes a reset module 266 configured to control read/write operations of the storage space 265 and initiate a reset in case of exceptions.

Furthermore, the result memory 260 further includes an address mapping module 267 configured to configure and store mapping codes from storage addresses of the sub-storage spaces in the storage space 365 to storage addresses in the upper-computer control apparatus 100.

Furthermore, the result memory 260 further includes a write-set mapping module 268, including a plurality of registers respectively corresponding to the plurality of sub-storage spaces. By modifying a flag value in a register of the write-set mapping module, the check result stored in the sub-storage space corresponding to the register may be cleared. This mode of clearing stored check results is referred to as write clearing. Alternatively, the result memory 260 may not include the write-set mapping module 268. In this case, the check result stored in the sub-storage space may be cleared when read by the upper-computer control apparatus 100, and the setting of the corresponding result interrupt state register is also cleared. This mode of clearing stored check results is referred to as read clearing. In practical applications, the read clearing mode is preferred, thereby reducing the hardware implementation cost. It should be noted that, the above modules included in the result memory 260 may be configured by hardware circuit or software or a combination thereof.

According to the CRC check system 1000 in the above embodiments, in situations where there is more to-be-checked data, the check on certain data sets may be completed earlier, and the upper-computer control apparatus 100 can clearly know the data set on which the check is completed and read the check result from the corresponding sub-storage space.

In some embodiments, the upper-computer control apparatus 100 further includes a system reset module configured to reset the non-volatilely programmed programmable CRC circuit 200 after valid transmission of all the data to be sent to the slave by the master is completed, to restore the non-volatilely programmed programmable CRC circuit 200 to a default state, that is, remove programmed parameters thereof. The valid transmission of all the data to be sent to the slave by the master refers to a situation in which the non-volatilely programmed programmable CRC circuit 200 completes the check on all the transmitted data sets, the check result generated by the non-volatilely programmed programmable CRC circuit 200 is consistent with the expected CRC result, and the data is successfully received by the slave. “Restore the programmable CRC circuit 200 to a default state” means that programmed parameters in the programmable CRC circuit 200 are removed, the internal circuit structure and the function of the programmable CRC circuit 200 are restored to default states, and various parameters of the programmable CRC circuit 200 may be re-configured.

According to the CRC check system 1000 in the above embodiments, after the data transmission from the master to the slave is completed, the programmable CRC circuit 200 is restored to the default state, and the various parameters of the programmable CRC circuit 200 may be re-configured according to an actual communication scenario for next data transmission.

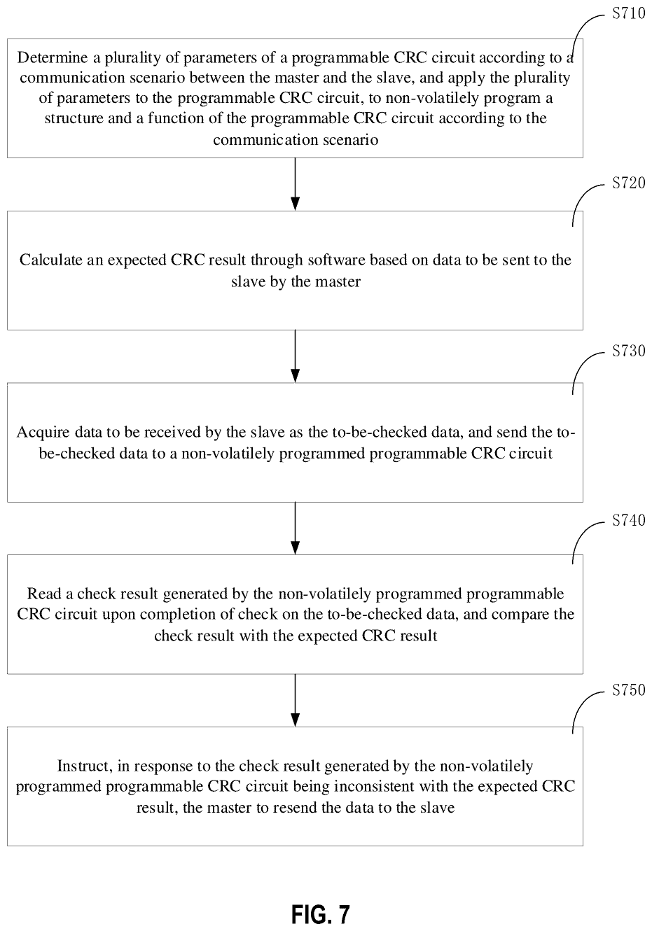

In another aspect of the present disclosure, a CRC check method is provided, for checking data sent from a master to a slave. Referring to FIG. 7, FIG. 7 is a flowchart of a CRC check method according to embodiments of the present disclosure. The CRC check method includes steps S710 to S750 as follows. It is easy to understand that the CRC check method is performed by a computing apparatus, for example, by the upper-computer control apparatus 100 in the foregoing embodiments.

In S710, a plurality of parameters of a programmable CRC circuit are determined according to a communication scenario between a master and a slave, and the plurality of parameters are applied to the programmable CRC circuit, to non-volatilely program a structure and a function of the programmable CRC circuit according to the communication scenario.

In S720, an expected CRC result is calculated through software based on data to be sent to the slave by the master.

In S730, data to be received by the slave is acquired as the to-be-checked data, and the to-be-checked data is sent to a non-volatilely programmed programmable CRC circuit.

In S740, a check result generated by the non-volatilely programmed programmable CRC circuit upon completion of check on the to-be-checked data is read, and is compared with the expected CRC result.

In S750, in response to the check result generated by the non-volatilely programmed programmable CRC circuit being inconsistent with the expected CRC result, the master is instructed to resend the data to the slave.

In some embodiments, the programmable CRC circuit includes: a parameter non-volatile programming sub-circuit configured to receive the plurality of parameters, and non-volatilely program a CRC check algorithm and an actual operating circuit structure of the programmable CRC circuit based on the plurality of parameters, a check sub-circuit configured to check the to-be-checked data to generate the check result, an interrupt sub-circuit configured to generate an interrupt signal in response to an event occurring during the check on the to-be-checked data by the non-volatilely programmed programmable CRC circuit, and a result memory configured to store the check result generated by the check sub-circuit.

In some embodiments, the check sub-circuit includes a first check sub-circuit and a second check sub-circuit with identical structures, the first check sub-circuit and the second check sub-circuit each include a serial CRC structure circuit and a parallel CRC structure circuit and are each configured to check the to-be-checked data to generate a check result; and the serial CRC structure circuit has a pipeline-stage-configurable circuit structure, and the parallel CRC structure circuit has a systolic matrix array carry structure.

In some embodiments, step S710 further includes: determining, according to the communication scenario between the master and the slave, one or more of the following parameters of the programmable CRC circuit: a lockstep enable parameter indicating whether to enable both the first check sub-circuit and the second check sub-circuit, a selection enable parameter indicating which of the serial CRC structure circuit and the parallel CRC structure circuit is selected, delay parameters of the first check sub-circuit and the second check sub-circuit when both the first check sub-circuit and the second check sub-circuit are enabled, a number of pipeline stages of the pipeline-stage-configurable circuit structure when the serial CRC structure circuit is selected, and a matrix configuration parameter of the systolic matrix array carry structure when the parallel CRC structure circuit is selected.

In some embodiments, the CRC check method further includes: classifying, according to master IDs and slave IDs, all the data to be sent to the slave by the master into one or more data sets, the data with identical master IDs and identical slave IDs belonging to a same data set. Step S720 further includes: calculating, in units of the data sets, one or more expected CRC results respectively corresponding to the one or more data sets through software. Step S740 further includes: reading one or more check results respectively corresponding to the one or more data sets generated by the non-volatilely programmed programmable CRC circuit upon completion of the check on the to-be-checked data in units of the data sets, and comparing the one or more check results respectively with the one or more expected CRC results.

In some embodiments, the CRC check method further includes: monitoring an interrupt signal generated by the interrupt sub-circuit of the programmable CRC circuit, and step S750 further includes: performing, in response to monitoring the interrupt signal, processing corresponding to the monitored interrupt signal.

In some embodiments, the interrupt sub-circuit of the non-volatilely programmed programmable CRC circuit is further configured to: generate, in response to an operational error of the non-volatilely programmed programmable CRC circuit, an internal error interrupt as the interrupt signal, and generate, in response to the non-volatilely programmed programmable CRC circuit generating a predetermined number of check results, a check result interrupt as the interrupt signal, and step S750 further includes: issuing, in response to monitoring the internal error interrupt, an instruction to fix an error, and instructing, in response to monitoring the check result interrupt, the result reading module to read the check result from the result memory of the non-volatilely programmed programmable CRC circuit for comparison.

In some embodiments, the interrupt sub-circuit of the programmable CRC circuit is further configured to generate, in a case where both the first check sub-circuit and the second check sub-circuit are enabled, the internal error interrupt when a check result generated by the first check sub-circuit is inconsistent with a check result generated by the second check sub-circuit, and step S750 further includes: resetting, in response to monitoring the internal error interrupt, the non-volatilely programmed programmable CRC circuit and re-perform the check on the to-be-checked data.

In some embodiments, the result memory of the non-volatilely programmed programmable CRC circuit includes, based on the plurality of parameters, a plurality of result interrupt state registers respectively corresponding to the plurality of data sets and a plurality of sub-storage spaces respectively corresponding to the plurality of data sets, each of the result interrupt state registers is configured to indicate completion of check on the corresponding data set, and each of the sub-storage spaces is configured to store a check result of the corresponding data set. S740 further includes: checking, in response to the monitoring module monitoring the check result interrupt, the one or more result interrupt state registers to determine the data set on which the check is completed, reading the check result generated by the non-volatilely programmed programmable CRC circuit from the sub-storage space corresponding to the data set on which the check is completed, and comparing the check result with the expected CRC result.

In some embodiments, the method further includes resetting the non-volatilely programmed programmable CRC circuit 200 after valid transmission of all the data to be sent to the slave by the master is completed.

For specific details of the CRC check method according to the present disclosure, refer to the above description of the CRC check system according to the present disclosure. Details are not described herein again.

In another aspect of the present disclosure, a non-transitory computer-readable storage medium is provided, having a computer program stored therein. When the computer program is executed by a processor, the CRC check method according to the present disclosure is implemented.

For specific details of the non-transitory computer-readable storage medium according to the present disclosure, refer to the above description of the CRC check system according to the present disclosure. Details are not described herein again.

In another aspect of the present disclosure, a computer program product is provided, including a computer program stored therein. When the computer program is executed by a processor, the CRC check method according to the present disclosure is implemented.

For specific details of the computer program product according to the present disclosure, refer to the above description of the CRC check system according to the present disclosure. Details are not described herein again.

The technical features in the above embodiments may be randomly combined. For concise description, not all possible combinations of the technical features in the above embodiments are described. However, all the combinations of the technical features are to be considered as falling within the scope described in this specification provided that they do not conflict with each other.

The above embodiments only describe several implementations of the present invention, and their description is specific and detailed, but cannot therefore be understood as a limitation on the patent scope of the invention. It should be noted that those of ordinary skill in the art may further make variations and improvements without departing from the conception of the present invention, and these all fall within the protection scope of the present invention. Therefore, the patent protection scope of the present invention should be subject to the appended claims.

What is claimed is:

1. A cyclic redundancy check (CRC) check system, for checking data sent from a master to a slave, comprising an upper-computer control apparatus and a programmable CRC circuit, the programmable CRC circuit being configured to check to-be-checked data to generate a check result;
wherein the upper-computer control apparatus is configured to:
determine a plurality of parameters of the programmable CRC circuit according to a communication scenario between the master and the slave, and apply the plurality of parameters to the programmable CRC circuit, to non-volatilely program a structure and a function of the programmable CRC circuit according to the communication scenario;
calculate an expected CRC result through software based on data to be sent to the slave by the master;
acquire data to be received by the slave as the to-be-checked data, and send the to-be-checked data to a non-volatilely programmed programmable CRC circuit;
read a check result generated by the non-volatilely programmed programmable CRC circuit upon completion of check on the to-be-checked data, and compare the check result with the expected CRC result; and
instruct, in response to the check result generated by the non-volatilely programmed programmable CRC circuit being inconsistent with the expected CRC result, the master to resend the data to the slave.

2. The system according to claim 1, wherein the programmable CRC circuit comprises:
a parameter non-volatile programming sub-circuit configured to receive the plurality of parameters, and non-volatilely program a CRC check algorithm and an actual operating circuit structure of the programmable CRC circuit based on the plurality of parameters;
a check sub-circuit configured to check the to-be-checked data to generate the check result;
an interrupt sub-circuit configured to generate an interrupt signal in response to an event occurring during the check on the to-be-checked data by the non-volatilely programmed programmable CRC circuit; and
a result memory configured to store the check result generated by the check sub-circuit.

3. The system according to claim 2, wherein the check sub-circuit comprises:
a first check sub-circuit and a second check sub-circuit with identical structures, the first check sub-circuit and the second check sub-circuit each comprising a serial CRC structure circuit and a parallel CRC structure circuit and being each configured to check the to-be-checked data to generate a check result; and
the serial CRC structure circuit having a pipeline-stage-configurable circuit structure, and the parallel CRC structure circuit having a systolic matrix array carry structure.

4. The system according to claim 3, wherein the upper-computer control apparatus is further configured to determine, according to the communication scenario between the master and the slave, one or more of the following parameters of the programmable CRC circuit:
a lockstep enable parameter indicating whether to enable both the first check sub-circuit and the second check sub-circuit;
a selection enable parameter indicating which of the serial CRC structure circuit and the parallel CRC structure circuit is selected;
delay parameters of the first check sub-circuit and the second check sub-circuit when both the first check sub-circuit and the second check sub-circuit are enabled;
a number of pipeline stages of the pipeline-stage-configurable circuit structure when the serial CRC structure circuit is selected; and
a matrix configuration parameter of the systolic matrix array carry structure when the parallel CRC structure circuit is selected.

5. The system according to claim 2, wherein the upper-computer control apparatus is further configured to:
classify, according to master IDs and slave IDs, all the data to be sent to the slave by the master into one or more data sets, the data with identical master IDs and identical slave IDs belonging to a same data set;
calculate, in units of the data sets, one or more expected CRC results respectively corresponding to the one or more data sets through software; and
read one or more check results respectively corresponding to the one or more data sets generated by the non-volatilely programmed programmable CRC circuit upon completion of the check on the to-be-checked data in units of the data sets, and compare the one or more check results respectively with the one or more expected CRC results.

6. The system according to claim 5, wherein the upper-computer control apparatus is further configured to:
monitor an interrupt signal generated by the interrupt sub-circuit of the non-volatilely programmed programmable CRC circuit; and
perform, in response to monitoring the interrupt signal, processing corresponding to the monitored interrupt signal.

7. The system according to claim 6, wherein the interrupt sub-circuit of the non-volatilely programmed programmable CRC circuit is further configured to:
generate, in response to an operational error of the non-volatilely programmed programmable CRC circuit, an internal error interrupt as the interrupt signal; and
generate, in response to the non-volatilely programmed programmable CRC circuit generating a predetermined number of check results, a check result interrupt as the interrupt signal; and
wherein the upper-computer control apparatus is further configured to:
issue, in response to monitoring the internal error interrupt, an instruction to fix an error; and
read, in response to monitoring the check result interrupt, the check result from the result memory of the non-volatilely programmed programmable CRC circuit for comparison.

8. The system according to claim 7, wherein the interrupt sub-circuit of the non-volatilely programmed programmable CRC circuit is further configured to generate, in a case where both the first check sub-circuit and the second check sub-circuit are enabled, the internal error interrupt when a check result generated by the first check sub-circuit is inconsistent with a check result generated by the second check sub-circuit; and
wherein the upper-computer control apparatus is further configured to reset, in response to monitoring the internal error interrupt, the non-volatilely programmed programmable CRC circuit and re-perform the check on the to-be-checked data.

9. The system according to claim 7, wherein the result memory of the non-volatilely programmed programmable CRC circuit comprises, based on the plurality of parameters, a plurality of result interrupt state registers respectively corresponding to the plurality of data sets and a plurality of sub-storage spaces respectively corresponding to the plurality of data sets, each of the result interrupt state registers being configured to indicate completion of check on the corresponding data set, and each of the sub-storage spaces being configured to store a check result of the corresponding data set; and
wherein the upper-computer control apparatus is further configured to:
check, in response to monitoring the check result interrupt, the one or more result interrupt state registers to determine the data set on which the check is completed,
read the check result generated by the non-volatilely programmed programmable CRC circuit from the sub-storage space corresponding to the data set on which the check is completed, and
compare the check result with the expected CRC result.

10. A CRC check method, for checking data sent from a master to a slave, comprising:
determining a plurality of parameters of a programmable CRC circuit according to a communication scenario between the master and the slave, and applying the plurality of parameters to the programmable CRC circuit, to non-volatilely program a structure and a function of the programmable CRC circuit according to the communication scenario;
calculating an expected CRC result through software based on data to be sent to the slave by the master;
acquiring data to be received by the slave as the to-be-checked data, and sending the to-be-checked data to a non-volatilely programmed programmable CRC circuit;
reading a check result generated by the non-volatilely programmed programmable CRC circuit upon completion of check on the to-be-checked data, and comparing the check result with the expected CRC result; and
instructing, in response to the check result generated by the non-volatilely programmed programmable CRC circuit being inconsistent with the expected CRC result, the master to resend the data to the slave.

11. A non-transitory computer-readable storage medium, having a computer program stored therein, wherein when the computer program is executed by a processor, a CRC check method for checking data sent from a master to a slave comprising:
determining a plurality of parameters of a programmable CRC circuit according to a communication scenario between the master and the slave, and applying the plurality of parameters to the programmable CRC circuit, to non-volatilely program a structure and a function of the programmable CRC circuit according to the communication scenario;
calculating an expected CRC result through software based on data to be sent to the slave by the master;
acquiring data to be received by the slave as the to-be-checked data, and sending the to-be-checked data to a non-volatilely programmed programmable CRC circuit;
reading a check result generated by the non-volatilely programmed programmable CRC circuit upon completion of check on the to-be-checked data, and comparing the check result with the expected CRC result; and
instructing, in response to the check result generated by the non-volatilely programmed programmable CRC circuit being inconsistent with the expected CRC result, the master to resend the data to the slave.
